(19) United States
(12) Patent Application Publication
(10) Pub. No.: US 2017/0316961 A1
(43) Pub. Date: Nov. 2, 2017

(54) SUBSTRATE LIQUID PROCESSING METHOD, SUBSTRATE LIQUID PROCESSING APPARATUS, AND COMPUTER-READABLE STORAGE MEDIUM THAT STORES SUBSTRATE LIQUID PROCESSING PROGRAM

(71) Applicant: Tokyo Electron Limited, Tokyo (JP)

(72) Inventors: Mitsunori Nakamori, Kumamoto (JP); Jun Nonaka, Kumamoto (JP)

(21) Appl. No.: 15/518,094

(22) PCT Filed: Oct. 20, 2015
(86) PCT No.: PCT/JP2015/079615

§ 371 Date: Apr. 10, 2017

(30) Foreign Application Priority Data
Oct. 21, 2014 (JP) 2014-214418
Sep. 8, 2015 (JP) 2015-176525

(51) Int. Cl. H01L 21/67; H01L 21/304; H01L 21/687; B08B 3/00

(52) U.S. Cl. CPC H01L 21/67051; H01L 21/68742; H01L 21/67265; H01L 21/304; B08B 3/00

(57) ABSTRACT

Disclosed is a substrate liquid processing method including: performing a liquid processing step of liquid-processing a substrate with a processing liquid, a rinse processing step of rinsing the liquid-processed substrate with a rinse liquid, and a water-repellency processing step of imparting water-repellency to the rinsed substrate with a water-repellent liquid; then, performing a cleaning processing step of cleaning the water-repellency-imparted substrate with a functional liquid; then, performing an alcohol processing step of bringing the cleaned substrate in contact with alcohol; and then, performing a drying processing step of drying the substrate.

### TECHNICAL FIELD

The present disclosure relates to a substrate liquid processing method and a substrate liquid processing apparatus for performing a water-repellency processing on a surface of a liquid-processed substrate with a water-repellent liquid and then drying the surface, and also relates to a computer-readable storage medium that stores a substrate liquid processing program.

### BACKGROUND

Conventionally, in manufacturing, for example, semiconductor parts or flat panel displays, a substrate liquid processing apparatus is used to perform a liquid processing on a substrate such as, for example, a semiconductor wafer or a liquid crystal substrate, using various processing liquids, and thereafter, perform a drying processing of removing a processing liquid remaining on the substrate by rotating the substrate at a high speed.

In the substrate liquid processing apparatus, with the miniaturization of patterns such as, for example, circuit patterns and etching mask patterns formed on the surface of the substrate and the increase in aspect ratio, the patterns formed on the surface of the substrate may collapse due to the action of the surface tension of the processing liquid remaining on the substrate during the drying processing.

Therefore, in the conventional substrate liquid processing apparatus, a water repellent liquid (e.g., a silylating agent) is supplied to the substrate to impart water-repellency to the surface of the substrate when the drying processing is performed. Thereafter, deionized water is supplied as a cleaning liquid to the substrate, and the substrate is rotated at a high speed to remove the cleaning liquid from the surface thereof. As described above, in the conventional substrate liquid processing apparatus, the surface of the substrate is imparted with water-repellency, so that the contact angle between the patterns and the rinsing liquid is brought into a state close to 90 degrees. Thus, the force for collapsing the pattern with the cleaning liquid is reduced, thereby suppressing the collapse of the patterns during the drying processing (see Patent Document 1).

The water-repellent liquid used for imparting water-repellency to the surface of the substrate may render the surface of the substrate water water-repellent (hydrophobic) by the action of the contained hydrophobic group. Since the water-repellent liquid contains a lot of impurities, the impurities may remain on the surface of the substrate after the water-repellency processing. However, even though a cleaning liquid of deionized water is supplied to the substrate subjected to the water-repellency processing, it is impossible to remove the impurities remaining on the surface of the substrate.

### PRIOR ART DOCUMENT

### Patent Document

Patent Document 1: Japanese Patent Laid-Open Publication No. 2010-114439

### DISCLOSURE OF THE INVENTION

### Problems to be Solved

The present disclosure is to provide a technique capable of removing impurities remaining on the surface of the substrate subjected to a water-repellency processing.

### Means to Solve the Problems

According to an exemplary embodiment, the present disclosure provides a substrate liquid processing method including: performing a liquid processing step of liquid-processing a substrate with a processing liquid, a rinse processing step of rinsing the liquid-processed substrate with a rinse liquid, and a water-repellency processing step of imparting water-repellency to the rinsed substrate with a water-repellent liquid; then, performing a cleaning processing step of cleaning the water-repellency-imparted substrate with a functional liquid; then, performing an alcohol processing step of bringing the cleaned substrate in contact with alcohol; and then, performing a drying processing step of drying the substrate.

A deionized water processing step of rinsing the substrate with deionized water may be performed between the alcohol processing step and the drying processing step.

The functional water may be any one of alkaline electrolytic ionized water, ammonia water, hydrogen water, and ozone water.

The functional water and the alcohol may be supplied from the same nozzle.

The functional water and the alcohol may be supplied to the substrate by changing a mixing ratio thereof stepwise or continuously at a time of transition from the cleaning processing step to the alcohol processing step.

The alcohol processing step may include: forming a streak-like flow of the functional water; and supplying the alcohol to a position closer to a central side of the substrate than the streak-like flow.

The forming the streak-like flow of the functional water may include moving a supply position of the functional water from the central side of the substrate to an outer peripheral side.

According to another exemplary embodiment, the present disclosure provides a substrate liquid processing apparatus including: a substrate holding unit that holds a substrate; a processing liquid supply unit that supplies a processing liquid to the substrate; a rinse liquid supply unit that supplies a rinse liquid to the substrate liquid-processed with the processing liquid; a water-repellent liquid supply unit that supplies a water-repellent liquid to the substrate rinsed with the rinse liquid; a functional water supply unit that supplies a functional water to the substrate imparted with water-repellency with the water-repellent liquid; an alcohol supply unit that supplies alcohol to the substrate cleaned with the functional water; and a controller that controls to supply the water-repellent liquid from the water-repellent liquid supply unit to the substrate rinsed with the rinse liquid, supply the functional water from the functional water supply unit to the substrate, supply the alcohol from the alcohol supply unit to the substrate, and then, dry the substrate

The controller may perform a control to supply the rinse liquid to the substrate after supplying the alcohol from the alcohol supply unit to the substrate.

The functional water and the alcohol may be supplied from the same nozzle.

The functional water and the alcohol may be supplied to the substrate by changing a mixing ratio thereof stepwise or continuously at a time of transition from the supply of the functional water to the supply of the alcohol.

Further, at the time of transition from supply of the functional water to supply of the alcohol, a streak-like flow of the functional water may be formed on the substrate and the alcohol is supplied to a position closer to a central side of the substrate than the streak-like flow.

Further, the supply position of the functional water forming the streak-like flow is moved from the central side of the substrate to an outer peripheral side.

According to still another exemplary embodiment, the present disclosure provides a non-transitory computer-readable storage medium that stores a substrate liquid processing program that, when executed, to cause a computer to perform a processing on a substrate using a substrate liquid processing apparatus including: a substrate holding unit that holds a substrate; a processing liquid supply unit that supplies a processing liquid to the substrate; a rinse liquid supply unit that supplies a rinse liquid to the substrate liquid-processed with the processing liquid; a water-repellent liquid supply unit that supplies a water-repellent liquid to the substrate rinsed with the rinse liquid; a functional water supply unit that supplies a functional water to the substrate imparted with water-repellency with the water-repellent liquid; an alcohol supply unit that supplies alcohol to the substrate cleaned with the functional water; and a controller that controls the units. A control is performed to supply the water-repellent liquid from the water-repellent liquid supply unit to the substrate rinsed with the rinse liquid, supply the functional water from the functional water supply unit to the substrate, supply the alcohol from the alcohol supply unit to the substrate, and then, dry the substrate.

### BRIEF DESCRIPTION OF THE DRAWINGS

FIG. 1 is a plan view illustrating a substrate liquid processing apparatus.

FIG. 2 is a side view illustrating a substrate liquid processing unit.

FIG. 3 is an explanatory view illustrating a nozzle group.

FIGS. 4A and 4B are flowcharts illustrating a substrate liquid processing method.

FIGS. 5A and 5B are explanatory views illustrating the substrate liquid processing method (FIG. 5A illustrates a liquid processing step, and FIG. 5B illustrates a rinse processing step).

FIGS. 6A and 6B are explanatory views illustrating the substrate liquid processing method (a water-repellency processing step).

FIGS. 7A and 7B are explanatory views illustrating the substrate liquid processing method (a cleaning processing step).

FIGS. 8A and 8B are explanatory views illustrating the substrate liquid processing method (FIG. 8A illustrates an alcohol processing step, and FIG. 8B illustrates a drying processing step).

FIGS. 9A to 9D are explanatory views illustrating the substrate liquid processing method.

### DETAILED DESCRIPTION TO EXECUTE THE INVENTION

Hereinafter, a specific exemplary embodiment of the substrate liquid processing apparatus and the substrate liquid processing method according to the present disclosure will be described with reference to the drawings.

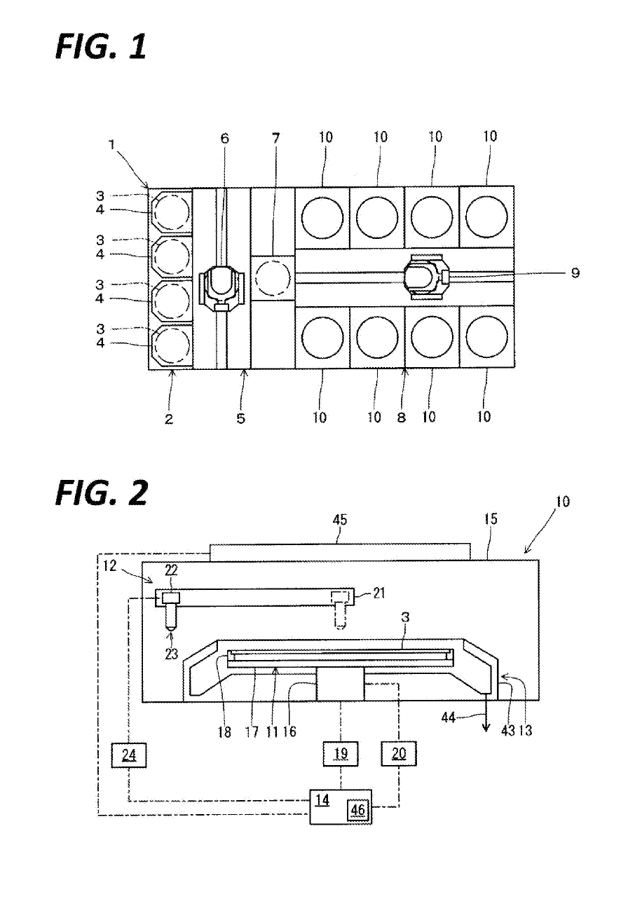

As illustrated in FIG. 1, the substrate liquid processing apparatus 1 includes a carry-in/out section 2 at the front end. Carriers 4 each accommodating a plurality of (e.g., twenty five (25)) substrates 3 (in this case, semiconductor wafers) are carried into and carried out and are placed from side to side the carry-in/out section 2.

Further, the substrate liquid processing apparatus 1 includes a conveyance section 5 at the rear side of the carry-in/out section 2. A substrate conveyance device 6 is disposed on the front side of the conveyance section 5, and a substrate delivery table 7 is disposed on the rear side. In the conveyance section 5, a substrate 3 is conveyed between any one of the carriers 4 placed in the carry-in/out section 2 and the substrate delivery table 7 by using the substrate conveyance device 6.

Further, the substrate liquid processing apparatus 1 includes a processing section 8 on the rear side of the conveyance section 5. A substrate conveyance device 9 is arranged at the center of the processing section 8 to extend in the back and forth direction. Substrate liquid processing units 10 for liquid-processing the substrates 3 are arranged side by side in the back and forth direction on both left and right sides of the substrate conveyance device 9. In the processing section 8, the substrate 3 is conveyed between the substrate delivery table 7 and one of the substrate liquid processing units 10 by using the substrate conveyance device 9, and the substrate liquid processing is performed on the substrate 3 by using the substrate liquid processing unit 10.

As illustrated in FIG. 2, the substrate liquid processing unit 10 includes a substrate holding unit 11, a supply unit 12, and a recovery unit 13, which are controlled by a controller 14. The substrate holding unit 11 rotates the substrate 3 while holding the substrate 3. The supply unit 12 supplies various liquids or gases to the substrate 3. The recovery unit 13 recovers the various liquids or gases supplied to the substrate 3. The controller 14 controls the operation of the substrate liquid processing unit 10, as well as the operation of the entire substrate liquid processing apparatus 1.

The substrate holding unit 11 includes a rotating shaft 16 that vertically extends substantially in the center of the inside of a processing chamber 15. A disk-shaped turntable 17 is horizontally attached to the upper end of the rotating shaft 16. A plurality of substrate holders 18 are attached to the outer peripheral edge of the turntable 17 at regular intervals in the circumferential direction.

The rotating shaft 16 is connected with a substrate rotating mechanism 19 and a substrate lifting mechanism 20. The rotating operation of the substrate rotating mechanism 19 and the lifting operation of the substrate lifting mechanism 20 are controlled by the controller 14.

The substrate holding unit 11 holds the substrate 3 horizontally with the substrate holders 18 of the turntable 17. Further, the substrate holding unit 11 rotates the substrate 3 held by the turntable 17 by driving the substrate rotating mechanism 19. Further, the substrate holding unit 11 lifts the turntable 17 and the substrate 3 by driving the substrate lifting mechanism 20.

The supply unit 12 includes a guide rail 21 provided inside the processing chamber 15, an arm 22 movably attached to the guide rail 21, a nozzle group 23 including a plurality of nozzles attached to a lower portion of the tip of the arm 22. The arm 22 is connected with a nozzle moving mechanism 24 driven and controlled by the controller 14.

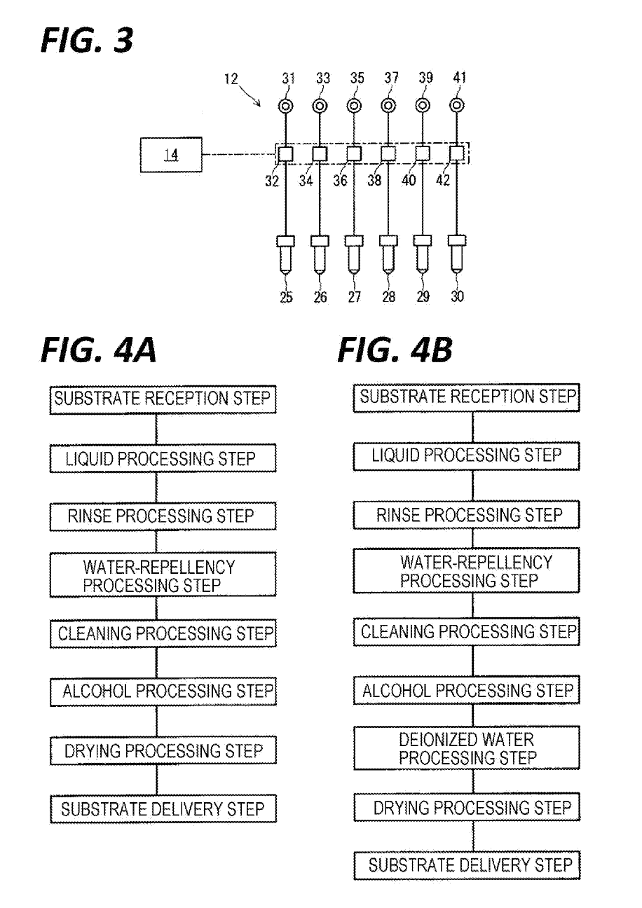

As illustrated in FIG. 3, the nozzle group 23 includes a processing liquid supply nozzle 25, a deionized water supply nozzle 26, an IPA supply nozzle 27, a water-repellent liquid supply nozzle 28, a functional water supply nozzle 29, and an inert gas supply nozzle 30. The processing liquid supply nozzle 25 is connected with a processing liquid source 31 via a flow rate adjustor 32 to supply a processing liquid (here, a chemical liquid for cleaning). The deionized water liquid supply nozzle 26 is connected with a deionized water liquid source 33 via a flow rate adjustor 34 to supply deionized water. The IPA supply nozzle 27 is connected with an IPA source 35 via a flow rate adjustor 36 to supply isopropyl alcohol (IPA). The water-repellent liquid supply nozzle 28 is connected with a water-repellent liquid source 37 via a flow rate adjustor 38 to supply a water-repellent liquid (here, a silylating agent). The functional water supply nozzle 29 is connected with a functional water source 39 via a flow rate adjustor 40 to supply a functional water (here, an electrolytic ionized water of pH 8 or more). The inert gas supply nozzle 30 is connected with an inert gas source 41 via a flow rate adjustor 42 to supply an inert gas (here, nitrogen gas). The flow rate and the opening/closing of each of the flow rate adjustors 32, 34, 36, 38, 40, 42 are controlled by the controller 14. Carbon dioxide gas may be previously dissolved in the deionized water to be supplied from the deionized water supply nozzle 26. Therefore, generation of static electricity may be suppressed when the deionized water flows on the surface of the substrate 3. Even though static electricity is generated on the surface of the substrate 3, the static electricity may be removed.

The supply unit 12 horizontally moves the nozzles 25 to 30 between a standby position outside the outer peripheral edge of the substrate 3 and a start position above the central portion of the substrate 3 by the nozzle moving mechanism 24. Further, the supply unit 12 ejects the liquid or gas at a predetermined flow rate adjusted by the flow rate adjustors 34, 36, 38, 40, 42 from the nozzles 25 to 30 toward the surface (upper surface) of the substrate 3. A plurality of arms 22 may be provided to be movable independently from each other, and one or more of the nozzles 25 to 30 may be distributed and attached to each arm. All of the nozzles 25 to 30 may be arranged on a single common arm. Further, instead of providing the deionized water supply nozzle 26 and the IPA supply nozzle 27, it is also possible to provide one supply nozzle for supplying both deionized water and IPA so as to continuously perform the switch from the IPA supply to the deionized water supply and the switch from the deionized water supply to the IPA supply. Therefore, during the switching of the deionized water and the IPA, the surface of the substrate 3 may be suppressed from being exposed such that the substrate 3 hardly comes into contact with the surrounding atmosphere (surrounding gas).

As illustrated in FIG. 2, the recovery unit 13 includes an annular recovery cup 43 arranged around the turntable 17. An opening, which is slightly larger than the turntable 17 (substrate 3), is formed in the upper end portion of the recovery cup 43. A drain 44 is connected to the lower end portion of the recovery cup 43.

The recovery unit 13 recovers, for example, the processing liquid supplied to the surface of the substrate 3 by the recovery cup 43 and discharges the processing liquid from the drain 44 to the outside. The drain 44 recovers not only the liquid but also the gas (atmosphere) inside the processing chamber 15. Therefore, clean air supplied from a fan filter unit (FFU) 45 provided in the upper portion of the processing chamber 15 is caused to flow down inside the processing chamber 15. The FFU 45 is configured to perform the switching between a state of supplying the clean air and a state of supplying clean dry air (CDA) having a humidity lower than that of the clean air. The humidity inside the processing chamber 15 (around the substrate 3) may be lowered by causing the CDA to flow down inside the processing chamber 15. Therefore, the FFU 45 functions as a dry gas supply unit that supplies CDA as a dry gas to the inside of the processing chamber 15. The FFU 45 is driven and controlled by the controller 14.

The substrate liquid processing apparatus 1 is configured as described above and controlled by the controller 14 in accordance with various programs stored in a storage medium 46 provided in the controller 14 (computer), thereby performing a processing on the substrate 3. Here, the storage medium 46 stores various setting data and programs, and is constituted by any known storage medium such as, for example, a memory (e.g., a ROM or a RAM) or a disk-like storage medium (e.g., a hard disk, a CD-ROM, a DVD-ROM, or a flexible disk).

Then, the substrate liquid processing apparatus 1 performs a processing on the substrate 3 as described below (see, e.g., FIG. 4) in accordance with the substrate liquid processing program stored in the storage medium 46.

First, the substrate liquid processing apparatus 1 receives the substrate 3 to be conveyed by the substrate conveyance device 9, by the substrate liquid processing unit 10 (substrate reception step).

In the substrate receiving step, the controller 14 moves up the turntable 17 to a predetermined position. Then, one substrate 3 conveyed from the substrate conveyance device 9 to the inside of the processing chamber 15 is received in a state of being held horizontally by the substrate holders 18. Thereafter, the turntable 17 is moved down to a predetermined position. In the substrate receiving step, the nozzle group 23 (including the processing liquid supply nozzle 25, the deionized water supply nozzle 26, the IPA supply nozzle 27, the water-repellent liquid supply nozzle 28, and the inert gas supply nozzle 30) is retreated to the standby position outside the outer periphery of the turntable 17.

Next, the substrate liquid processing apparatus 1 performs a liquid processing on the surface of the substrate 3 with a processing liquid such as, for example, an etching liquid or a cleaning liquid (liquid processing step).

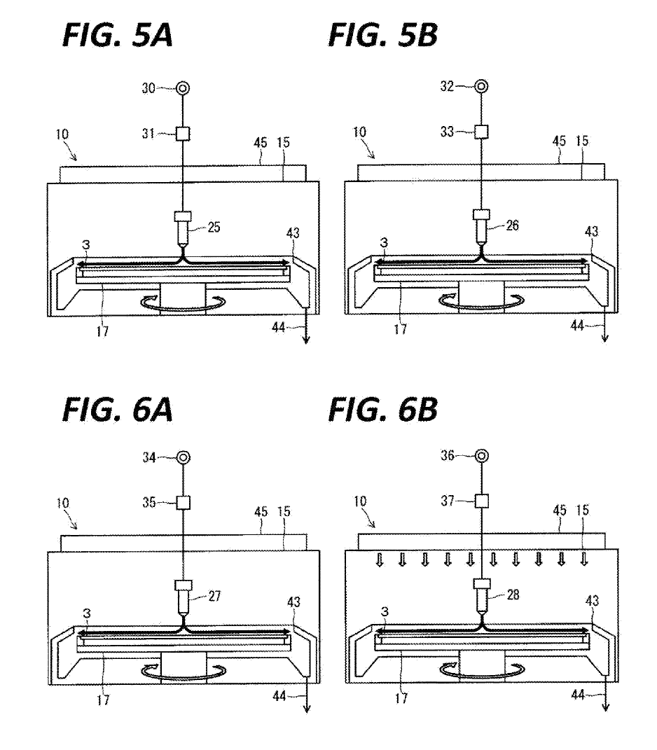

In the liquid processing step, as illustrated in FIG. 5A, the controller 14 moves the processing liquid supply nozzle 25 to the start position above the central portion of the substrate 3. Further, the substrate 3 is rotated by rotating the turntable 17 at a predetermined rotation speed. Thereafter, the processing liquid whose flow rate has been adjusted to a predetermined flow rate by the flow rate adjustor 32 is supplied from the processing liquid source 31 to the processing liquid supply nozzle 25, and ejected from the processing liquid supply nozzle 25 toward the surface (upper surface) of the substrate 3. Thus, the surface of the substrate 3 is liquid-processed with the processing liquid. The processing liquid supplied to the substrate 3 is shaken off to the outside of the outer peripheral edge of the substrate 3 by the centrifugal force of the rotating substrate 3, recovered by the recovery cup 43, and discharged to the outside from the drain 44. After the processing liquid is supplied for a predetermined time, the ejection of the processing liquid is stopped by the flow rate adjustor 32. As such, in the liquid processing step, the processing liquid supply nozzle 25, the flow rate adjustor 32, and the processing liquid source 31 mainly function as a processing liquid supply unit. In the liquid processing step, clean air or CDA is selected as a gas to be supplied from the FFU 45 depending on the type of the processing liquid, and the inside of the processing chamber 15 is maintained at a high degree of cleanliness.

Next, the substrate liquid processing apparatus 1 performs a rinse processing on the surface of the substrate 3 with a rinse liquid (rinse processing step).

In the liquid processing step, as illustrated in FIG. 5B, the controller 14 moves the deionized water supply nozzle 26 to the start position above the central portion of the substrate 3 in a state where the substrate 3 is continuously rotated by rotating the turntable 17 at a predetermined rotation speed. Thereafter, the deionized water whose flow rate has been adjusted to a predetermined flow rate by the flow rate adjustor 34 is supplied as the rinse liquid from the deionized water source 33 to the deionized water supply nozzle 26, and ejected from the deionized water supply nozzle 26 toward the surface of the substrate 3. Thus, the surface of the substrate 3 is rinsed with the rinse liquid by rinsing away the processing liquid on the surface of the substrate 3 with the rinse liquid. The rinse liquid supplied to the substrate 3 is shaken off to the outside of the outer peripheral edge of the substrate 3 by the centrifugal force of the rotating substrate 3, recovered by the recovery cup 43, and discharged to the outside from the drain 44. After the rinse liquid is supplied for a predetermined time, the ejection of the rinse liquid is stopped by the flow rate adjustor 34. As such, in the rinse processing step, the deionized water supply nozzle 26, the flow rate adjustor 34, and the deionized water source 33 mainly function as a rinse liquid supply unit.

Next, the substrate liquid processing apparatus 1 performs a water-repellency processing on the surface of the substrate 3 with a water-repellent liquid (water-repellency processing step).

In the water-repellency processing step, as illustrated in FIG. 6A, the controller 14 moves the IPA supply nozzle 27 to the start position above the central portion of the substrate 3 in a state where the substrate 3 is continuously rotated by rotating the turntable 17 at a predetermined rotation speed. Thereafter, the IPA whose flow rate has been adjusted to a predetermined flow rate by the flow rate adjustor 36 is supplied from the IPA source 35 to the IPA supply nozzle 27, and ejected from the IPA supply nozzle 27 toward the surface of the substrate 3. Thus, the rinse liquid on the surface of the substrate 3 is replaced with IPA. The IPA supplied to the substrate 3 is shaken off to the outside of the outer peripheral edge of the substrate 3 by the centrifugal force of the rotating substrate 3, recovered by the recovery cup 43, and discharged to the outside from the drain 44. After the IPA is supplied for a predetermined time, the ejection of the IPA is stopped by the flow rate adjustor 36.

Further, in the water-repellency processing step, as illustrated in FIG. 6B, the controller 14 moves the water-repellent liquid supply nozzle 28 to the start position above the central portion of the substrate 3. Thereafter, the water-repellent liquid whose flow rate has been adjusted to a predetermined flow rate by the flow rate adjustor 38 is supplied from the water-repellent liquid source 37 to the water-repellent supply nozzle 28, and ejected from the water-repellent liquid supply nozzle 28 toward the surface of the substrate 3. Thus, the surface of the substrate 3 is imparted with water-repellency. The water-repellent liquid supplied to the substrate 3 is shaken off to the outside of the outer peripheral edge of the substrate 3 by the centrifugal force of the rotating substrate 3, recovered by the recovery cup 43, and discharged to the outside from the drain 44. After the water-repellent liquid is supplied for a predetermined time, the ejection of the water-repellent liquid is stopped by the flow rate adjustor 38. As such, in the water-repellency processing step, the water-repellent liquid supply nozzle 28, the flow rate adjustor 38, and the water-repellent liquid source 37 mainly function as a water-repellent liquid supply unit. In the water-repellency processing step, the controller 14 selects CDA as a gas to be supplied from the FFU 45 to the processing chamber 15 to reduce the humidity inside the processing chamber 15.

Next, the substrate liquid processing apparatus 1 performs a cleaning processing on the surface of the substrate 3 with a cleaning liquid (cleaning processing step).

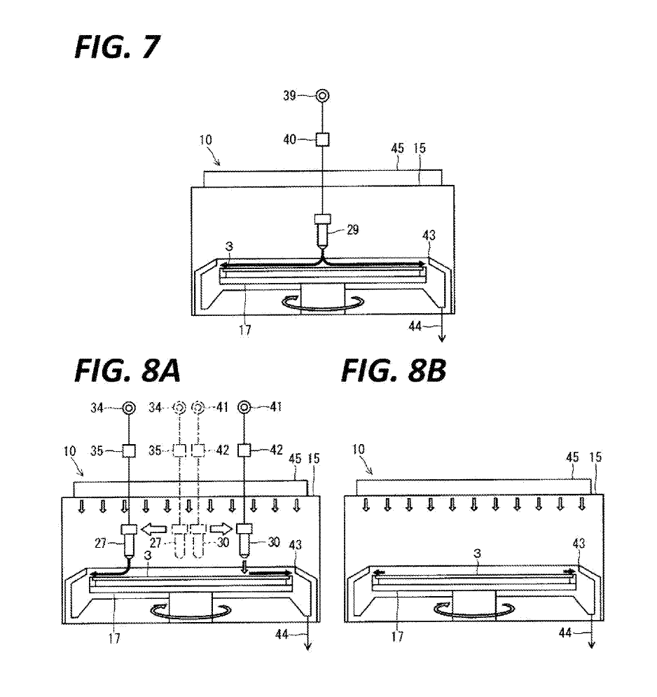

In the cleaning processing step, as illustrated in FIG. 7A, the controller 14 moves the functional water supply nozzle 29 to the start position above the central portion of the substrate 3 in a state where the substrate 3 is continuously rotated by rotating the turntable 17 at a predetermined rotation speed. Thereafter, the functional water whose flow rate has been adjusted to a predetermined flow rate by the flow rate adjustor 40 is supplied as the cleaning liquid from the functional water source 39 to the functional water supply nozzle 29, and ejected from the functional water supply nozzle 29 toward the surface of the substrate 3. Thus, the surface of the substrate 3 is cleaned with the functional water. When the substrate 3 is subjected to a water-repellency processing with the water-repellent liquid, impurities may remain on the surface of the substrate 3 after the water-repellency processing because the water-repellent liquid contains many impurities. Thus, the impurities remaining on the surface of the substrate 3 may be removed by cleaning the substrate 3, which has been subjected to the water-repellency processing, with the cleaning liquid. The functional water supplied to the substrate 3 is shaken off to the outside of the outer peripheral edge of the substrate 3 by the centrifugal force of the rotating substrate 3, recovered by the recovery cup 43, and discharged to the outside from the drain 44. After the functional water is supplied for a predetermined time, the ejection of the functional water is stopped by the flow rate adjustor 40. As such, in the cleaning processing step, the functional water supply nozzle 29, the flow rate adjustor 40, and the functional water source 39 mainly function as the cleaning liquid supply unit. As the functional water, an alkaline liquid is used, and examples of the alkaline liquid include alkaline (preferably pH 8 or more) electrolyzed ionized water, ammonia water which is diluted to 1 ppm to 20 ppm, hydrogen water, and ozone water. The water-repellent liquid and the cleaning liquid (functional water) may be ejected simultaneously from the same nozzle or different nozzles at the time of transition from the water-repellency processing step to the cleaning processing step. Therefore, the surface of the substrate 3 may be suppressed from being exposed during the switching from the water-repellent liquid to the cleaning liquid so that the surface of the substrate 3 may not come into contact with the surrounding atmosphere (surrounding gas). At this time, the mixing ratio of the water-repellent liquid and the cleaning liquid may be changed stepwise, or gradually and continuously. Here, “mixing” includes both the mixing before the ejection from the nozzle and the mixing on the wafer W after the ejection. In the latter case, the “mixing ratio” is a ratio of the ejection flow rates from the respective nozzles. Since the surface tension of the liquid present on the surface of the substrate 3 is changed gradually by changing the mixing ratio in this manner, the surface of the substrate 3 may be easily suppressed from being exposed to outside air, as compared with a case where the surface tension is changed abruptly. For example, the mixing ratio of the water-repellent liquid and the cleaning liquid is 1:0 at the beginning of the supply, but the supply amount of the cleaning liquid is increased with the lapse of time, and the supply amount of the water-repellent liquid is decreased. Thereafter, when the mixing ratio reaches a predetermined mixing ratio, the supply is performed for a predetermined time at that ratio. Thereafter, the supply amount of the cleaning liquid may be increased stepwise or continuously, and the supply amount of the water-repellent liquid may be decreased. Further, IPA, which is a liquid having a surface tension lower than that of the cleaning liquid, may be contained in the cleaning liquid and supplied in the cleaning processing step. As a result, the cleaning liquid easily permeates into the pattern of the water-repellent substrate 3, thereby improving the cleaning effect. Further, in this case, after the IPA containing cleaning liquid is supplied, only the cleaning liquid may be supplied. When the cleaning liquid is newly supplied in a state where the IPA containing cleaning liquid permeates into the pattern, the newly supplied cleaning liquid also easily penetrates into the pattern. Thus, the cleaning effect may be further improved. In the cleaning processing step, the controller 14 selects clean air as a gas to be supplied from the FFU 45, and supplies the clean air to the processing chamber 15 to increase the humidity inside the processing chamber 15.

Next, the substrate liquid processing apparatus 1 performs an alcohol processing of bringing alcohol (drying liquid) into contact with the surface of the substrate 3 (drying processing step). As the drying liquid, alcohol having a higher volatility and lower surface tension than the cleaning liquid is used. Here, an electrolytic ionized water of pH 8 or more is used as the cleaning liquid, and IPA is used as the drying liquid.

In the alcohol processing step, as illustrated in FIG. 8A, the controller 14 moves the IPA supply nozzle 27 and the inert gas supply nozzle 30 to the start position above the central portion of the substrate 3 in a state where the substrate 3 is continuously rotated by rotating the turntable 17 at a predetermined rotation speed. Thereafter, the IPA whose flow rate has been adjusted to a predetermined flow rate by the flow rate adjustor 36 is supplied as the drying liquid from the IPA source 35 to the IPA supply nozzle 27, and ejected from the IPA supply nozzle 27 toward the surface of the substrate 3. In addition, the inert gas whose flow rate has been adjusted to a predetermined flow rate by the flow rate adjustor 42 (here, nitrogen gas) is supplied from the inert gas source 41 to the inert gas supply nozzle 30, and ejected from the inert gas supply nozzle 30 toward the surface of the substrate 3. Then, the IPA supply nozzle 27 and the inert gas supply nozzle 30 are moved from the start position above the substrate 3 toward a position above the outer peripheral edge. The moving direction of the two nozzles 27 and 30 may be the reverse direction or the same direction, but the IPA supply nozzle 27 is always positioned radially outward of the inert gas supply nozzle 30. Accordingly, the IPA ejected from the IPA supply nozzle 27 to the substrate 3 is forcibly moved toward the outer peripheral edge of the substrate 3 by the inert gas ejected from the inert gas supply nozzle 30. Therefore, drying of the substrate 3 may be facilitated. In this manner, the cleaning liquid on the surface of the substrate 3 is replaced with the drying liquid by supplying IPA to the substrate 3. The drying liquid supplied to the substrate 3 is shaken off to the outside of the outer peripheral edge of the substrate 3 by the centrifugal force of the rotating substrate 3, recovered by the recovery cup 43, and discharged to the outside from the drain 44. After the drying liquid is supplied for a predetermined time, the ejection of the drying liquid is stopped by the flow rate adjustor 36. As such, in the alcohol processing step, the IPA supply nozzle 27, the flow rate adjustor 36, and the IPA source 35 mainly function as the alcohol supply unit. In the alcohol processing step, the controller 14 supplies the drying liquid to the substrate 3 at a flow rate lower than the flow rate of the cleaning liquid in the cleaning processing step. At the time of transition from the cleaning processing step to the alcohol processing step, the functional water and the alcohol may be ejected from the same nozzle, so that the surface of the substrate 3 is suppressed from being exposed and coming into contact with the surrounding atmosphere (surrounding gas) at the time of switching from the functional water to the alcohol. Further, the mixing ratio of the functional water and the alcohol may be changed stepwise, or the mixing ratio may be changed gradually and continuously.

Therefore, since the wettability of the substrate 3 is changed gradually, the surface of the substrate 3 may be easily suppressed from being exposed to outside air, as compared with a case where the wettability is changed abruptly. For example, the mixing ratio of the functional water and the alcohol is 1:0 at the beginning of the supply, but the supply amount of the alcohol is increased and the supply amount of the functional water is decreased with the lapse of time. Thereafter, when the mixing ratio reaches a predetermined mixing ratio, the supply is performed for a predetermined time at that ratio. Thereafter, the supply amount of the alcohol may be increased stepwise or continuously, and the supply amount of the functional water may be decreased stepwise or continuously.

Next, as illustrated in FIG. 4A, the substrate liquid processing apparatus 1 removes the drying liquid from the substrate 3 to dry the substrate 3 (drying processing step). As illustrated in FIG. 4B, the substrate liquid processing apparatus 1 may perform a deionized water processing step of rinsing the substrate 3 subjected to the alcohol processing step by supplying deionized water to the substrate 3 before performing the drying processing step. The deionized water processing step can be performed in the same manner as the rinse processing step. In that case, in the drying processing step, the substrate 3 is dried by removing the rinse liquid from the substrate 3. At the time of transition from the alcohol processing step to the rinse processing step, the alcohol and the deionized water may be ejected from the same nozzle, and the mixing ratio of the alcohol and deionized water may be changed stepwise, or gradually and continuously. Therefore, the alcohol processing step and the rinse processing step may be performed at the same time, and it is possible to suppress liquid breakage on the substrate 3 and shorten the time required for the processings.

In the drying processing step, as illustrated in FIG. 8B, the controller 14 continuously rotates the substrate 3 by rotating the turntable 17 at a predetermined rotation speed (a rotation speed higher than the rotation speed in the liquid processing step, the rinse processing step, the water-repellency processing step, and the cleaning processing step). Thus, the drying liquid remaining on the substrate 3 is shaken off to the outside of the outer peripheral edge of the substrate 3 by the action of the centrifugal force of the rotating substrate 3, and removed from the surface of the substrate 3 so that the surface of the substrate 3 is dried. In the drying processing step, the nozzle group 23 (including the processing liquid supply nozzle 25, the deionized water supply nozzle 26, the IPA supply nozzle 27, the water-repellent liquid supply nozzle 28, and the inert gas supply nozzle 30) is retreated to the standby position outside the outer periphery of the turntable 17. Further, in the alcohol processing step and the drying processing step, the controller 14 selects CDA as a gas to be supplied from the FFU 45, and supplies the CDA to the processing chamber, so that the humidity inside the processing chamber 15 is reduced as compared with the humidity in the cleaning processing step. Therefore, the drying of the substrate 3 is facilitated.

Finally, the substrate liquid processing apparatus 1 delivers the substrate 3 from the substrate liquid processing unit 10 to the substrate conveyance device 9 (substrate delivery step).

In the substrate delivery step, the controller 14 moves up the turntable 17 to a predetermined position. Then, the substrate 3 held by the turntable 17 is delivered to the substrate conveyance device 9. Thereafter, the turntable is moved down to a predetermined position.

As described above, in the substrate liquid processing apparatus 1 (the substrate liquid processing method performed by the substrate liquid processing apparatus 1), the substrate 3, which has been subjected to the water-repellency processing with the water-repellent liquid, is cleaned with the alkaline functional water immediately after the water-repellency processing, and then, the substrate 3 is dried.

As described above, when the substrate 3 is subjected to a water-repellency processing with the water repellent liquid, a large amount of impurities contained in the water-repellent liquid immediately after the water-repellent processing is likely to be attached to the surface of the substrate due to the affection of the hydrophobic group contained in the water-repellent liquid, and may remain as particles on the dried substrate 3. Therefore, the impurities may be removed from the surface of the substrate 3 by cleaning the surface of the substrate 3 with alkaline functional water immediately after the water-repellency processing. Thus, the substrate 3 may be satisfactorily dried.

Further, in the substrate liquid processing apparatus 1 (the substrate liquid processing method performed by the substrate liquid processing apparatus 1), the drying processing of the substrate 3 is performed by replacing the functional water, which has been used for the cleaning, with the drying liquid having a higher volatility than that of the functional water after the cleaning processing, and then, removing the drying liquid from the substrate 3.

When the substrate 3 is subjected to a water-repellency processing with the water-repellent liquid, impurities may remain on the surface of the substrate 3 after the water-repellency processing because the water-repellent liquid contains many impurities. Thus, the impurities remaining on the surface of the substrate 3 may be removed by supplying the functional water to the substrate 3, which has been subjected to the water-repellency processing.

Further, in the substrate liquid processing apparatus (the substrate liquid processing method performed by the substrate liquid processing apparatus 1), the substrate 3 subjected to the water-repellency processing is cleaned with the functional water before the alcohol processing.

In the case where the substrate 3 is subjected to the water-repellency processing with the water-repellent liquid, and the alcohol processing is performed immediately thereafter, it is difficult to remove impurities contained in the water-repellent liquid from the substrate 3. Therefore, the impurities may remain on the substrate 3. Thus, the impurities may be satisfactorily removed by supplying the functional water to the substrate 3 immediately after the water-repellency processing (before the alcohol processing).

In the substrate liquid processing apparatus 1, when changing the type of the liquid used for processing the substrate 3, the processing with the subsequent liquid (e.g., the alcohol processing with IPA) is started after the processing with the preceding liquid (e.g., the cleaning processing with the functional water) is completed. However, the processing with the subsequent liquid may also be started during the processing with the preceding liquid. For example, a case of transition from a cleaning processing step performed for cleaning impurities contained in a water-repellent liquid with a functional water to an alcohol processing step with IPA will be described below.

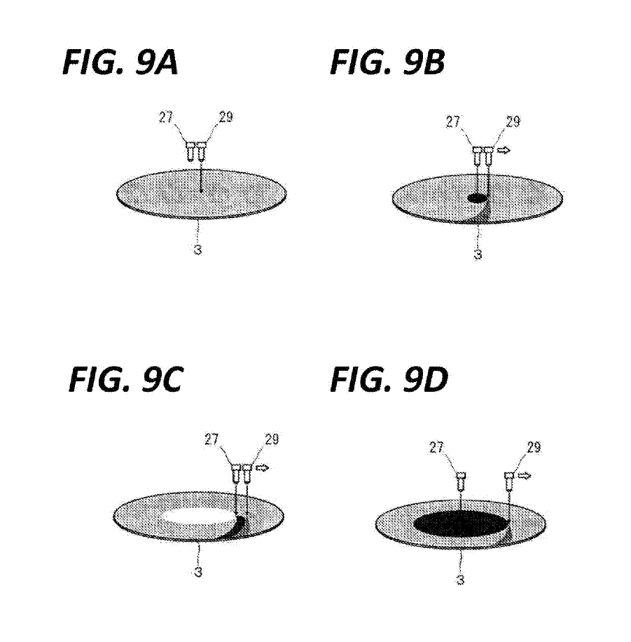

First, as illustrated in FIG. 9A, the controller 14 moves the functional water supply nozzle 29 to the start position above the central portion of the substrate 3 in a state where the substrate 3 is continuously rotated by rotating the turntable 17 at a predetermined rotation speed, and moves the IPA supply nozzle 27 to a position adjacent to the functional water supply nozzle 29. Then, functional water is ejected from the functional water supply nozzle 29 toward the center of the surface of the substrate 3. Then, as illustrated in FIG. 9B, the functional water supply nozzle 29 is moved from a position above the central portion of the substrate 3 toward the outside of the outer peripheral edge of the substrate 3 while ejecting the functional water, and the IPA supply nozzle 27 is moved together with the functional water supply nozzle 29. When the IPA supply nozzle 27 is positioned above the central portion of the substrate 3, IPA is ejected from the IPA supply nozzle 27 toward the center of the substrate 3 as a drying liquid. At that time, the flow rate and/or the rotation speed are controlled such that a streak-like flow including the IPA and the functional water is formed on the surface of the substrate 3. In order to form the streak-like flow, the rotation speed of the substrate 3 may be lower than that in the cleaning treatment step, or the supply amount of the functional water may be reduced. In particular, reducing the supply amount of the functional water is more desirable, because it leads to reduction in consumption of the functional water. The region through which the streak-like flow passes is covered with a liquid film of the functional water which is thinner than the liquid film of the functional water in the cleaning processing step. Then, as illustrated in FIG. 9C, the functional water supply nozzle 29 and the IPA supply nozzle 27 are moved toward the upper side of the outer peripheral edge of the substrate 3. At that time, the functional water supplied from the functional water supply nozzle 29 flows toward the outer peripheral edge of the substrate 3 while maintaining the streak-like flow on the surface of the substrate 3. Further, since a predetermined amount of IPA is supplied from the IPA supply nozzle 27 together with the functional water, a streak-like flow including IPA and functional water is formed. Thus, the impurities remaining on the surface of the substrate 3 may be removed by the functional water contained in the streak-like flow. Furthermore, since IPA having a low surface tension is mixed, it is possible to form a streak-like flow which is not discontinued. Thus, impurities remaining on the surface of the substrate 3 may be uniformly removed. Further, the functional water easily permeates into the pattern of the substrate 3, thereby improving the cleaning effect. In the region through which the streak-like flow passes, the liquid film of the functional water is gradually replaced with a liquid film of IPA having a surface tension lower than that of the functional water, so that the surface of the substrate 3 is not exposed. Further, the concentration of IPA is high at the upstream end of the streak-like flow. Thus, the drying region spreads concentrically on a region inward from the IPA supply position. Therefore, since the cleaning processing and the drying processing may be performed by the streak-like flow at the same time, the time of the drying processing may be shortened, and thus, the throughput of the substrate liquid processing apparatus 1 may be enhanced. Furthermore, the cleaning effect may be enhanced by forming the streak-like flow.

As illustrated in FIG. 9D, the functional water supply nozzle 29 is moved from a position above the central portion of the substrate 3 toward the outer peripheral edge of the substrate 3 while ejecting the functional water, and the IPA supply nozzle 27 is positioned above the central portion of the substrate 3 such that IPA is ejected from the IPA supply nozzle 27 toward the central portion of the substrate 3 as a drying liquid. At that time, the functional water supplied from the functional water supply nozzle 29 flows toward the outer peripheral edge of the substrate 3 while maintaining a streak-like flow on the surface of the substrate 3, and thus, a streak-like flow including IPA and functional water is formed. Thus, the impurities remaining on the surface of the substrate 3 may be removed by the functional water contained in the streak-like flow. Further, since IPA having a low surface tension is mixed, it is possible to form a streak-like flow which is not discontinued. In addition, since the streak-like flow is moved from the upper side of the central portion of the substrate 3 toward the outer peripheral edge of the substrate 3, impurities remaining on the surface of the substrate 3 may be uniformly removed. Further, the functional water easily permeates into the pattern of the substrate 3, thereby improving the cleaning effect. The region through which the streak-like flow passes is covered with a liquid film of the functional water, which is thinner than the liquid film of the functional water in the cleaning processing step. However, since the liquid film of the functional water is gradually replaced with a liquid film of IPA, the surface of the substrate 3 is not exposed. Further, since the IPA is ejected from the upper side of the central portion of the substrate 3, the inward region of the substrate 3 where the streak-like flow is present is covered with the liquid film of the IPA, so that the surface of the substrate 3 is not exposed. According to the exemplary embodiment, the drying processing step may be performed immediately after the functional water supply nozzle 29 reaches the outer periphery of the substrate 3. Since this drying processing step is the same as the drying processing step described in the previous exemplary embodiment, descriptions thereof are omitted.

As described above, since the drying liquid removal step may be performed after the cleaning processing by the streak-like flow, the time of the drying processing may be shortened, and thus, the throughput of the substrate liquid processing apparatus 1 may be enhanced. Further, the cleaning effect may be enhanced by forming the streak-like flow after the cleaning processing step. Further, the cleaning processing may be performed by the streak-like flow without exposing the surface of the substrate 3.

1. A substrate liquid processing method comprising:
performing a liquid processing step of liquid-processing a substrate with a processing liquid, a rinse processing step of rinsing the liquid-processed substrate with a rinse liquid, and a water-repellency processing step of imparting water-repellency to the rinsed substrate with a water-repellent liquid;
then, performing a cleaning processing step of cleaning the water-repellency-imparted substrate with a functional liquid;
then, performing an alcohol processing step of bringing the cleaned substrate in contact with alcohol; and
then, performing a drying processing step of drying the substrate.

2. The substrate liquid processing method of claim 1, wherein a deionized water processing step of rinsing the substrate with deionized water is performed between the alcohol processing step and the drying processing step.

3. The substrate liquid processing method of claim 1, wherein the functional water is any one of alkaline electrolytic ionized water, ammonia water, hydrogen water, and ozone water.

4. The substrate liquid processing method of claim 1, wherein the functional water and the alcohol are supplied from the same nozzle.

5. The substrate liquid processing method of claim 1, wherein the functional water and the alcohol are supplied to the substrate by changing a mixing ratio thereof stepwise or continuously at a time of transition from the cleaning processing step to the alcohol processing step.

6. The substrate liquid processing method of claim 1, wherein the alcohol processing step includes steps of: forming a streak-like flow of the functional water; and supplying the alcohol to a position closer to a central side of the substrate than the streak-like flow.

7. The substrate liquid processing method of claim 6, wherein the step of forming the streak-like flow of the functional water includes a step of moving a supply position of the functional water from the central side of the substrate to an outer peripheral side.

8. A substrate liquid processing apparatus comprising:
a substrate holding unit that holds a substrate;
a processing liquid supply unit that supplies a processing liquid to the substrate;
a rinse liquid supply unit that supplies a rinse liquid to the substrate liquid-processed with the processing liquid;
a water-repellent liquid supply unit that supplies a water-repellent liquid to the substrate rinsed with the rinse liquid;
a functional water supply unit that supplies a functional water to the substrate imparted with water-repellency with the water-repellent liquid;
an alcohol supply unit that supplies alcohol to the substrate cleaned with the functional water; and
a controller that performs a control to supply the water-repellent liquid from the water-repellent liquid supply unit to the substrate rinsed with the rinse liquid, supply the functional water from the functional water supply unit to the substrate, supply the alcohol from the alcohol supply unit to the substrate, and then, dry the substrate.

9. The substrate liquid processing apparatus of claim 8, wherein the controller performs a control to supply the rinse liquid to the substrate after supplying the alcohol from the alcohol supply unit to the substrate.

10. The substrate liquid processing apparatus of claim 8, wherein the functional water and the alcohol are supplied to the substrate from the same nozzle.

11. The substrate liquid processing apparatus of claim 8, wherein the functional water and the alcohol are supplied to the substrate by changing a mixing ratio thereof stepwise or continuously at a time of transition from the supply of the functional water to the supply of the alcohol.

12. The substrate liquid processing apparatus of claim 8, wherein, at the time of transition from supply of the functional water to supply of the alcohol, a streak-like flow of the functional water is formed on the substrate and the alcohol is supplied to a position closer to a central side of the substrate than the streak-like flow.

13. The substrate liquid processing apparatus of claim 12, wherein the supply position of the functional water forming the streak-like flow is moved from the central side of the substrate to an outer peripheral side.

14. A non-transitory computer-readable storage medium that stores a substrate liquid processing program that, when executed, to cause a computer to perform a processing on a substrate using a substrate liquid processing apparatus including: a substrate holding unit that holds a substrate; a processing liquid supply unit that supplies a processing liquid to the substrate; a rinse liquid supply unit that supplies a rinse liquid to the substrate liquid-processed with the processing liquid; a water-repellent liquid supply unit that supplies a water-repellent liquid to the substrate rinsed with the rinse liquid; a functional water supply unit that supplies a functional water to the substrate imparted with water-repellency with the water-repellent liquid; an alcohol supply unit that supplies alcohol to the substrate cleaned with the functional water; and a controller that controls the units,
wherein a control is performed to supply the water-repellent liquid from the water-repellent liquid supply unit to the substrate rinsed with the rinse liquid, supply the functional water from the functional water supply unit to the substrate, supply the alcohol from the alcohol supply unit to the substrate, and then, dry the substrate.
